(19) United States
(12) Patent Application Publication
(10) Pub. No.: US 2016/0322775 A1
(43) Pub. Date: Nov. 3, 2016

(54) Large-Aperture Laser Amplifier Side-Pumped by Multi-Dimensional Laser Diode Stack

(71) Applicant: ACADEMY OF OPTO-ELECTRONICS, CHINESE ACADEMY OF SCIENCES, Beijing (CN)

(72) Inventors: Zhongwei FAN, Beijing (CN); Jisi QIU, Beijing (CN); Xiongxin TANG, Beijing (CN); Tianzhuo ZHAO, Beijing (CN)

(21) Appl. No.: 15/108,457

(22) PCT Filed: Dec. 27, 2013
(86) PCT No.: PCT/CN2013/090634

§ 371 Date: Jun. 27, 2016

(51) Int. Cl. H01S 3/0941; H01S 3/042; H01S 3/094; H01S 3/06; H01S 5/40; H01S 5/022

(52) U.S. Cl. CPC H01S 3/0941; H01S 5/4025; H01S 5/0228; H01S 3/094057; H01S 3/0604; H01S 3/0606; H01S 3/042

(57) ABSTRACT

A large-aperture laser amplifier side-pumped by a multi-dimensional laser diode stack, which comprises: multiple pumping light source assemblies; a laser medium, of which the shape is a prismoid, wherein both the upside surface and the underside surface of the prismoid are polygonal, and the number of the edges of the polygon is the same as the number of the pumping light source assemblies; and a cooling device. Each side of the laser medium is provided with a pumping light source assembly; the pumping light emitted from the semiconductor laser diode stack is shaped by the beam shaping element, coupled by the coupling duct, and then enters from the side of the laser medium for side-pumping, and thereby amplifying the laser beam incident from the upside surface of the prismoid of the laser medium.

### TECHNICAL FIELD

The disclosure relates to the technical field of laser amplification devices, and in particular to a large-aperture laser amplifier side-pumped by a multi-dimensional laser diode stack.

### BACKGROUND

In existing technologies, since the single bar of a semiconductor laser diode is limited by a highest power and a package structure, the total light-emitting area of a stack generally is much greater than the section area of a laser medium. As a fine coupled device, a light guide can compress a light beam onto a small laser medium from a big area, and has advantages of high-efficiency, uniform light and conciseness.

As shown in FIG. 1, all present laser amplification devices based on a big-area semiconductor laser diode stack 10′, of which laser beams are shaped by a beam shaping element 40′ and coupled by a coupling duct 20′, adopt an end-face pumping mode and have defects as follows.

1. For one same laser medium 30′ (or called a working medium), if to enable a laser beam to obtain a higher gain, it is need to increase the number of the semiconductor laser diode stacks 10′ (equivalent to increasing the height H′ of the coupling duct 20′), then following problems are caused:

(1) in the design of the coupling duct 20′, the aperture of the laser medium 30, the height H′ and the length L′ of the coupling duct 20′ have a relationship. In the case that the aperture of the laser medium 30′ keeps unchanged, the increase in the height H′ of the coupling duct 20′ would result in a reduction in the coupling efficiency and the beam quality of the pump light at the exit of the coupling duct 20′; thus, the gain factor of the amplified laser is reduced and the beam quality of amplified laser is reduced;

(2) when there are many semiconductor laser diode stacks 10′, if one of the semiconductor laser diode stacks 10′ has a fault, it is very troublesome to maintain and repair and it is need to disassemble all the semiconductor laser diode stacks 10′ to eliminate the fault.

2. After a pumping beam passes through the coupling duct 20′ to reach the laser medium 30′, the closer the pumping beam approaches the exit of the coupling duct 20′ in the laser medium 30′, the better the pumping beam is in quality; as the transmission in the laser medium 30′, the longer the transmission distance is, the worse the pumping beam is in quality; this results in an uneven gain in the pumping area and directly affects the quality of the amplified laser beam.

Thus, overcoming the defect existing in the present technology is a problem to be solved in this technical field.

### SUMMARY OF THE INVENTION

The problem to be solved by the disclosure is to provide a large-aperture laser amplifier side-pumped by a multi-dimensional laser diode stack, which is convenient to adjust, troubleshoot, maintain and repair.

The technical solution adopted by the disclosure is as follows.

A large-aperture laser amplifier side-pumped by a multi-dimensional laser diode stack is provided, which includes:

multiple pumping light source assemblies (10), wherein each pumping light source assembly (10) includes a semiconductor laser diode stack (11), a beam shaping element (13) and a coupling duct (12); the light exit near the semiconductor laser diode stack (11) is provided with the beam shaping element (13) and the coupling duct (12) in order;

a laser medium (20), of which the shape is a prismoid, wherein both the upside surface and the underside surface of the prismoid are polygonal, and the number of the edges of the polygon is the same as the number of the pumping light source assemblies (10), the upside polygon and the underside polygon of the prismoid are similar polygons; and a cooling device (30), which is used to cool the laser medium (20), wherein the laser medium (20) is located on the cooling device (30);

wherein each side of the laser medium (20) is provided with a pumping light source assembly (10), wherein in each pumping light source assembly (10), the pumping light emitted from the semiconductor laser diode stack (11) is shaped by the beam shaping element (13), coupled by the coupling duct (12), and then enters from the side of the laser medium (20) for side pumping, and thereby amplifying the laser beam incident from the upside surface or the underside surface of the prismoid of the laser medium (20) needing energy amplification.

Further, the pumping light is totally reflected in the laser medium (20).

Further, the shape of the laser medium (20) is a regular prismoid, of which both the upside surface and the underside surface are regular polygons.

Further, on a section of the laser medium (20) where the light path of the pump light transmission in the laser medium (20) is located on, supposing the included angle between the side edge and the underside edge of the section is θ₅, when the pump light is totally reflected on the underside surface of the prismoid, supposing n₁ represents an air refractive index, n₂ the refractive index of the laser medium (20), then

$${θ}_{5} = arcsin ( \frac{{n}_{1}}{{n}_{2}} ) ;$$

or,

on a section of the laser medium (20) where the light path of the pump light transmission in the laser medium (20) is located on, supposing the included angle between the side edge and the underside edge of the section is θ₅, when the pump light is totally reflected on the upside surface of the prismoid, supposing n₁ represents an air refractive index, n₂ represents the refractive index of the laser medium (20), then

$${θ}_{5} = arcsin ( \frac{{n}_{1}}{{n}_{2}} ) .$$

Further, the length of an edge of the polygon of the upside surface of the prismoid of the laser medium (20) is less than the length of a corresponding edge of the polygon of the underside surface, the edge length of the polygon of the upside surface of the prismoid is greater than or equal to 10 mm.

Further, the upside surface of the prismoid of the laser medium (20) is plated with a high-transmission film which is consistent with the wavelength of a laser needing energy amplification; the high-transmission film is used to transmit the laser needing energy amplification; the underside surface of the prismoid of the laser medium (20) is plated with a reflection film which is consistent with the wavelength of the laser needing energy amplification; and the reflection film is used to reflect the laser needing energy amplification; or,

the underside surface of the prismoid of the laser medium (20) is plated with a high-transmission film which is consistent with the wavelength of a laser needing energy amplification; the high-transmission film is used to transmit the laser needing energy amplification; the upside surface of the prismoid of the laser medium (20) is plated with a reflection film which is consistent with the wavelength of the laser needing energy amplification; and the reflection film is used to reflect the laser needing energy amplification.

Further, after the laser needing energy amplification enters from the upside surface of the prismoid of the laser medium (20) and extracts energy, the laser is reflected by the reflection film plated on the underside surface of the prismoid of the laser medium (20), extracts energy and then is emitted from the upside surface of the prismoid of the laser medium (20); specifically, the incident laser enters from the upside surface of the prismoid of the laser medium (20) perpendicularly, the incident laser is overlapped with the emitted laser path and is coaxially amplified; or, the incident laser enters from the upside surface of the prismoid of the laser medium (20) at an angle, then the laser is emitted out at a certain angle relative to the incident laser, the incident laser is not overlapped with the emitted laser path and is off-axially amplified; or,

after the laser needing energy amplification enters from the underside surface of the prismoid of the laser medium (20) and extracts energy, the laser is reflected by the reflection film plated on the upside surface of the prismoid of the laser medium (20), extracts energy and then is emitted from the underside surface of the prismoid of the laser medium (20); specifically, the incident laser enters from the underside surface of the prismoid of the laser medium (20) perpendicularly, the incident laser is overlapped with the emitted laser path and is coaxially amplified; or, the incident laser enters from the underside surface of the prismoid of the laser medium (20) at an angle, then the laser is emitted out at a certain angle relative to the incident laser, the incident laser is not overlapped with the emitted laser path and is off-axially amplified.

Further, while off-axial amplification, a reflector group is provided at the laser exit and through the reflector group an off-axial multi-pass amplification is conducted.

Further, the number of the pumping light source assemblies (10) is at least 3, correspondingly, the number of the edges of the polygon is at least 3.

Further, the underside surface of the prismoid of the laser medium (10) is located on the cooling device (30); the cooling method of the cooling device (30) is air cooling or water cooling; or,

the upside surface of the prismoid of the laser medium (10) is located on the cooling device (30); the cooling method of the cooling device (30) is air cooling or water cooling.

Further, when the laser amplifier is horizontally placed and used, the upside surface and the underside surface of the prismoid of the laser medium (20) are placed along the horizontal direction;

when the laser amplifier is vertically placed and used, the upside surface and the underside surface of the prismoid of the laser medium (20) are placed along the vertical direction.

Compared with the existing technology, the disclosure has advantages as follows:

in the pumping large-aperture laser medium, compared with the end-face pumping mode in the existing technology, the semiconductor laser diode stack provided in the disclosure is equivalent to being discomposed into several small areas to be packaged, which reduces the volume of each coupling duct and is convenient to adjust; moreover, when the semiconductor laser diode stack has a fault, it is easy to troubleshoot and convenient to maintain and repair; compared with the existing technology, the technology in the disclosure reduces the height of each coupling duct, improves the coupling efficiency of the pumping light at the exit of coupling duct and improves the quality of the light beam, and thus increases the gain factor of the amplified laser and improves the beam quality of the amplified output laser.

### BRIEF DESCRIPTION OF THE DRAWINGS

FIG. 1 shows a diagram of an end-face pumped laser amplification device according to an existing technology;

FIG. 2 shows a structure diagram of a side pumped laser amplification device according to the Embodiment 1 of the disclosure;

FIG. 3 shows a diagram of partial structure of a side pumped laser amplification device according to the Embodiment 1 of the disclosure;

FIG. 4 shows a structure diagram of a laser medium according to the Embodiment 1 of the disclosure;

FIG. 5a shows a cross-section diagram to illustrate how the pumping light is totally reflected in the laser medium when the pumping light enters from the left side of a normal according to the Embodiment 1 of the disclosure;

FIG. 5b shows a cross section diagram in the case that the number of the incident light rays being totally reflected is highest when the pumping light enters from the left side of a normal according to the Embodiment 1 of the disclosure;

FIG. 6a shows a cross-section diagram to illustrate how the pumping light is totally reflected in the laser medium when the pumping light enters from the right side of a normal according to the Embodiment 1 of the disclosure;

FIG. 6b shows a cross section diagram in the case that the number of the incident light rays being totally reflected is highest when the pumping light enters from the right side of a normal according to the Embodiment 1 of the disclosure;

FIG. 7 shows a diagram of a coaxial amplification according to the Embodiment 1 of the disclosure;

FIG. 8 shows a diagram of an off-axial amplification according to the Embodiment 1 of the disclosure;

FIG. 9 shows a structure diagram of a laser medium according to the Embodiment 2 of the disclosure;

FIG. 10 shows a structure diagram of a laser medium according to the Embodiment 3 of the disclosure;

FIG. 11 shows a structure diagram of a laser medium and part coupling duct according to the Embodiment 3 of the disclosure.

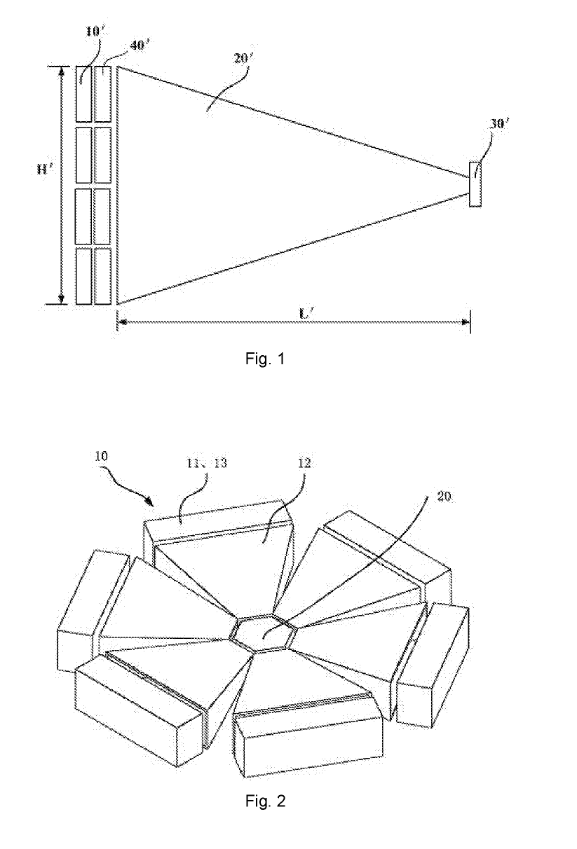

Numbers in the accompanying drawings are defined as follows:

10′ represents a semiconductor laser diode stack; 20′ represents a coupling duct; 30′ represents a laser medium; 40′ represents a beam shaping element; 10 represents a pumping light source assembly; 11 represents a semiconductor laser diode stack; 12 represents a coupling duct; 13 represents a beam shaping element; 20 represents a laser medium; 30 represents a cooling device.

### DETAILED DESCRIPTION OF THE EMBODIMENTS

For a better understanding of the purpose, technical scheme and advantages of the disclosure, the disclosure is described below in further detail in conjunction with accompanying drawings and embodiments. It should be understood that specific embodiments described below are used to illustrate the disclosure only not to limit the disclosure.

In addition, the features involved in each embodiment of the disclosure described below can be combined if not conflicted.

The disclosure provides a side pumped laser amplifier, which is applicable to a composite large-type laser device with a large-aperture laser medium and can obtain a higher energy gain. In another aspect, laser amplification devices based large-area semiconductor laser diode stack, which adopt a coupling duct to couple, generally are end-face pumping mode; this disclosure applies the laser amplification device to a side pumping mode.

### Embodiment 1

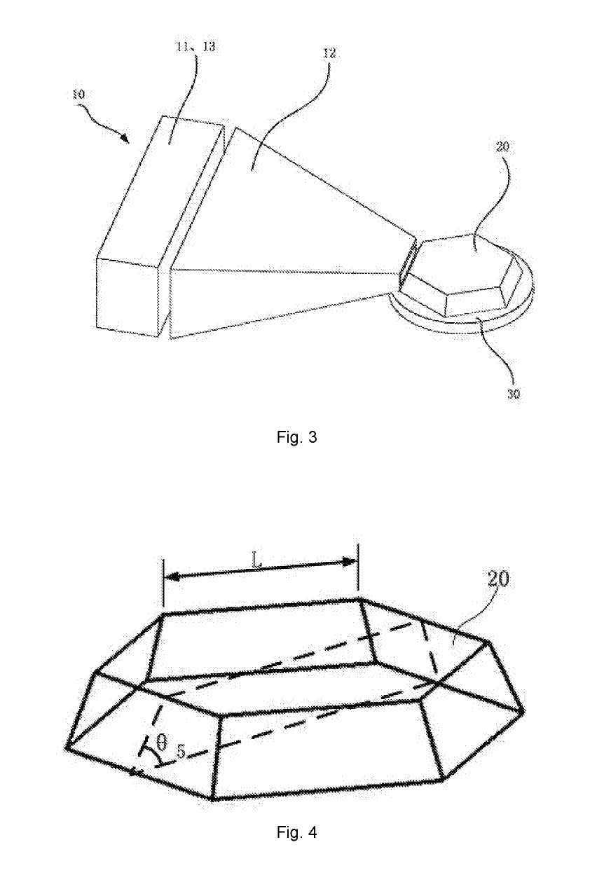

As shown in FIG. 2 and FIG. 3, the large-aperture laser amplifier side-pumped by a multi-dimensional laser diode stack provided by the Embodiment 1 of the disclosure includes multiple pumping light source assemblies 10, a laser medium 20 and a cooling device 30, wherein each pumping light source assembly 10 includes a semiconductor laser diode stack 11, a beam shaping element 13 (in FIG. 2 and FIG. 3 the semiconductor laser diode stack 11 and the beam shaping element 13 are designed into one piece) and a coupling duct 12; near the light exit of the semiconductor laser diode stack 11 is provided with the beam shaping element 13 and the coupling duct 12 in order, wherein the semiconductor laser diode stack 11 has a big area. The shape of the laser medium 20 is a regular prismoid, wherein both the upside surface and the underside surface of the regular prismoid are regular polygons, the upside surface is parallel to the underside surface, the edge length of the regular polygon of the upside surface is less than that of the underside surface, the number of the edges of the regular polygon is the same as the number of the pumping light source assemblies 10; the cooling device 30 is used to cool the laser medium 20, wherein the laser medium 20 is placed on the cooling device 30. In this embodiment, the underside surface of the prismoid of the laser medium 20 is placed on the cooling device.

It is understandable that the semiconductor laser diode stack 11, the coupling duct 12 and the cooling device 30 can adopt the universal devices used in this field. For example, the cooling way of the cooling device 30 can adopt air cooling or water cooling, that is, water or gas is put into the housing of the cooling device. The material of the laser medium 20 is a known technology in the laser field, which can be crystal, glass and the like. For the content known in this field, no limit is added here.

Each side of the laser medium 20 is provided with a pumping light source assembly 10, wherein in each pumping light source assembly 10, the pumping light emitted from the semiconductor laser diode stack 11 is shaped by the beam shaping element 13 (the light emitted by a laser diode is divergent, it is need to compress the divergence angle using the beam shaping element so as to shape the light as approximately parallel light to enter the coupling duct), coupled by the coupling duct 12, and then enters from the side of the laser medium 20 for side pumping, and thereby amplifying the laser beam incident from the upside surface of the regular prismoid of the laser medium 20 needing energy amplification.

The number of the pumping light source assemblies 10 is at least 3, corresponding, the number of the edges of the regular polygons is at least 3 too; for example, regular triangle, square, regular pentagon, regular hexagon and so on. This disclosure is described in detail by taking a regular hexagon as an example. The “multiple dimensions” mentioned above refers to the direction of one side pumping; for example, if the regular polygon is a regular pentagon, it is five dimensions.

As shown in FIG. 4, the aperture of the laser medium 20 is large, the edge length L of the regular polygon of the upside surface of the regular prismoid is greater than or equal to 10 mm. The upside surface of the regular prismoid of the laser medium 20 is plated with a high-transmission film which is consistent with the wavelength of a laser needing energy amplification; the high-transmission film is used to transmit the laser needing energy amplification; the underside surface of the prismoid of the laser medium 20 is plated with a reflection film which is consistent with the wavelength of the laser needing energy amplification; and the reflection film is used to reflect the laser needing energy amplification.

In a preferred embodiment, the pumping light is totally reflected in the laser medium 20. The pumping light output after being shaped by the coupling duct 12 is approximately parallel light; after entering into the laser medium 20, the light is totally reflected in the laser medium 20, wherein nearly each reflection is a total reflection; in this way, the pumping light would not be emitted out of the laser medium 20, the laser needing energy amplification can extract the pumping light to the greatest extent, the pumping light has a high energy utilization efficiency and can obtain a higher energy gain. If to enable the pumping light to be totally reflected in the laser medium 20, following conditions need to be satisfied:

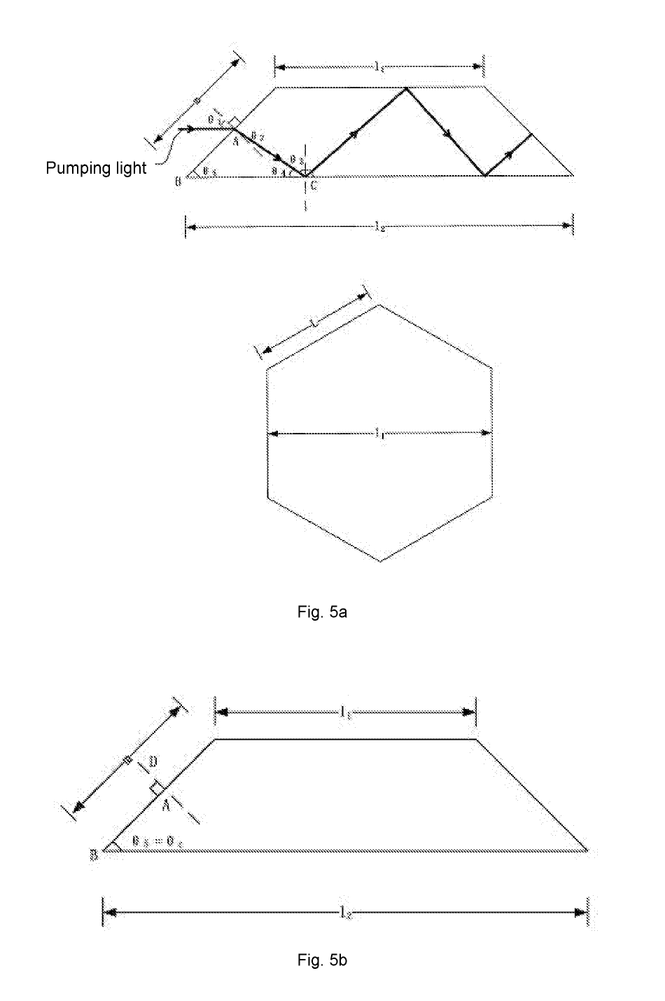

As shown in FIG. 5, n₁ represents an air refractive index, 2 represents the refractive index of the laser medium 20; for a section of the laser medium 20 where the light path of the pump light transmission in the laser medium (20) is located on, the edge length of the upside surface of the section is l₁, the edge length of the underside surface is l₂, the side edge length is m, the included angle between the side edge and the underside edge is θ₅, θ₁ represents an incident angle of the pumping light, θ₂ represents a refraction angle, total reflection occurs on the underside surface of the regular prismoid, θ₃ represents an incident angle when the pumping light is incident onto the underside surface of the regular prismoid.

When the light emitted from the semiconductor laser diode stack 11 is emitted out via the coupling duct 12, the angle θ₁ is changing, and the light is incident onto the laser medium 20 at various angles, θ₁ might be a horizontal incident angle or not, therefore, θ₁+θ₅≠90, θ₁ is a variable and θ₅ is a constant value.

According to the refraction law, n₁ sin θ₁=n₂ sin θ₂ \textcircled{1}.

(1) In the first condition, the pumping light enters from the left side of the normal of the incident plane of the laser medium 20;

the angle sum of a triangle ABC is 180 degrees, θ₅+θ₄+(90+θ₂)=180;

θ₅+(90−θ₃)+(90+θ₂)=180;

Always, θ₂=θ₃−θ₅ \textcircled{2}.

The critical condition of total reflection is:

$${θ}_{c} = arcsin ( \frac{{n}_{1}}{{n}_{2}} ) ;$$

if θ₃≧θ_{c}\textcircled{3}, the pumping light is always reflected in the laser medium 20 for many times.

Since θ₂≧0, θ₅≦θ_{c} \textcircled{5}.

From \textcircled{2}, θ₃=θ₂+θ₅ can be obtained; then, in conjunction with \textcircled{3}, θ₃=θ₂+θ₅≧θ_{c} can be obtained.

If the model of the laser medium 20 is fixed, θ₅ is a constant value and the refraction light θ₂ of the incident light meets θ₂≧θ_{c}−θ₅, total reflection can occur, that is, if

$${θ}_{1} \geq arcsin ( \frac{{n}_{2}}{{n}_{1}} sin ( {θ}_{c} - {θ}_{5} ) ) ,$$

total reflection can occur.

When θ₅=θ_{c}, θ₁ takes the smallest value 0, that is, total reflection can occur only if the incident light enters from the left side of the normal. Due to the edge AB, the incident angle θ₁ of the incident light relative to the normal cannot be greater than 90 degrees, that is, incident light within the area DAB can be totally reflected in FIG. 5b.

(2) In the second condition, the pumping light enters from the right side of the normal of the incident plane of the laser medium 20.

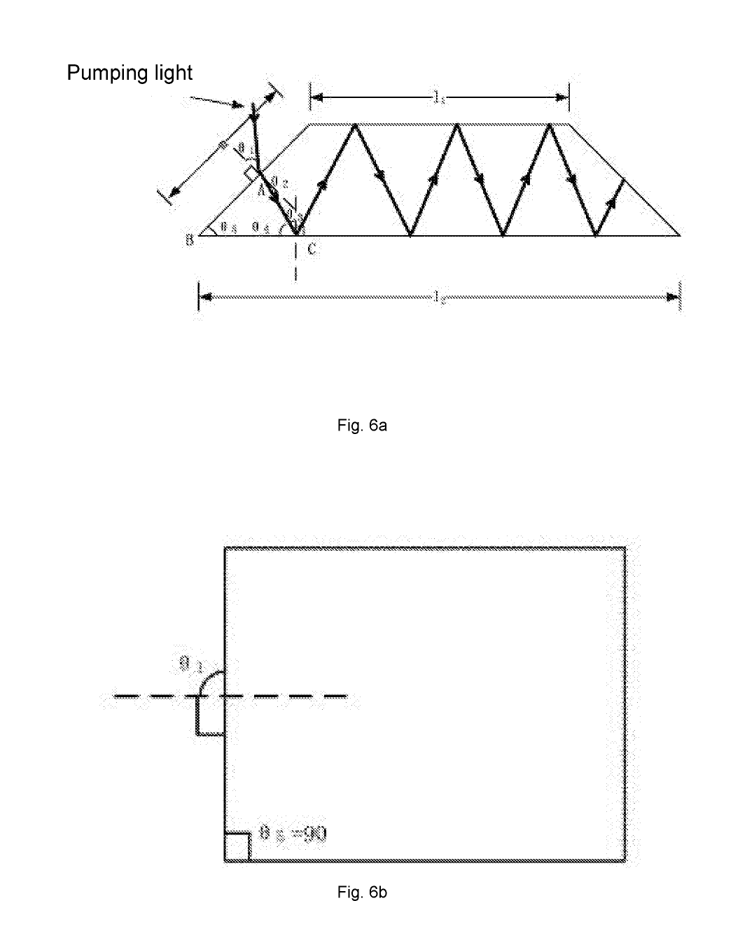

As shown in FIG. 6a, the angle sum of a triangle ABC is 180 degrees, θ₆+θ₄+(90−θ₂)=180;

θ₅+(90−θ₃)+(90−θ₂)=180;

Always, θ₂=θ₅−θ₃ \textcircled{4}.

The critical condition of total reflection is:

$${θ}_{c} = arcsin ( \frac{{n}_{1}}{{n}_{2}} ) ;$$

if θ₃≧θ_{c} \textcircled{3}, the pumping light is always reflected in the laser medium 20 for many times.

Since θ₂≧0, θ₅≧θ_{c} \textcircled{6}.

From \textcircled{4}, θ₃=θ₅−θ₂ can be obtained; then, in conjunction with \textcircled{3}, θ₃=θ₅−θ₂≧θ_{c}.

If the model of the laser medium 20 is fixed, θ₅ is a constant value and the refraction light θ₂ of the incident light meets θ₂≦θ₅−θ_{c}; total reflection can occur, that is, if

$${θ}_{1} \leq arcsin ( \frac{{n}_{2}}{{n}_{1}} sin ( {θ}_{5} - {θ}_{c} ) ) ,$$

total reflection can occur.

As shown in FIG. 6b, when θ₅=90°, θ₁ takes the biggest value, the number of the incident light being totally reflected is the highest. Since the angle of the light being emitted from the coupling duct is limited, when the light is incident onto the laser medium 20 from the right side of the normal, the incident angle is θ₁ less than 90 degrees.

To sum up:

from θ₅≦θ_{c} \textcircled{5} in (1) and θ₅≧θ_{c} \textcircled{6} in (2), it can be known that, when the incident light enters from different sides of the normal, the values of are θ₅ mutually conflicted to enable a total reflection. Once the model of the laser medium 20 is fixed and θ₅ takes a constant value, only the light on one side of the normal can be totally reflected when the light enters from the left or right side of the normal. When the light entering from the left side of the normal is totally reflected and θ₅=θ_{c}, the range of angle in which the incident light can be totally reflected is the biggest, that is, the light can be totally reflected in a range of 90 degrees; when the light entering from the right side of the normal is totally reflected and θ₅=90°, the range of angle in which the incident light can be totally reflected is the biggest, and the range of angle in which the light can be totally reflected is less than 90 degrees. Therefore, in a preferred embodiment, in order to enable a greatest number of light to be totally reflected and make the range of the incident angle biggest, θ₅=θ_{c}.

Instance:

l₁=30 mm, the air refractive index, n₁=1, the laser medium is neodymium glass, of which the refractive index n₂=1.53, m=10 mm.

The pumping light must be totally reflected in the laser medium 20,

$${θ}_{c} = arcsin ( \frac{{n}_{1}}{{n}_{2}} )$$

must be satisfied, then θ_{c}=40.81°.

Total reflection can occur if θ₃>40.81°.

If the light entering from the left side of the normal is totally reflected, θ₅≦40.81° must be satisfied.

If θ₅=30° and θ₂>10.81°, then θ₁>16.68°, that is, the light with incident angle greater than 16.68 degrees is totally reflected, the light can be totally reflected in a range of 73.32 degrees.

If θ₅=40.81° and θ₂>0°, then θ₁>0°, that is, the light with incident angle greater than 0 degrees is totally reflected, the light can be totally reflected in a range of 90 degrees. Since there are two critical conditions: the light enters from the left side of the normal; due to one edge (AB) of the laser medium 20, the incident angle of the incident light cannot be greater than 90 degrees, then θ₅=θ_{c}=40.81°, and there is the highest number of incident light rays that can be totally reflected.

Therefore, θ₅=40.81°.

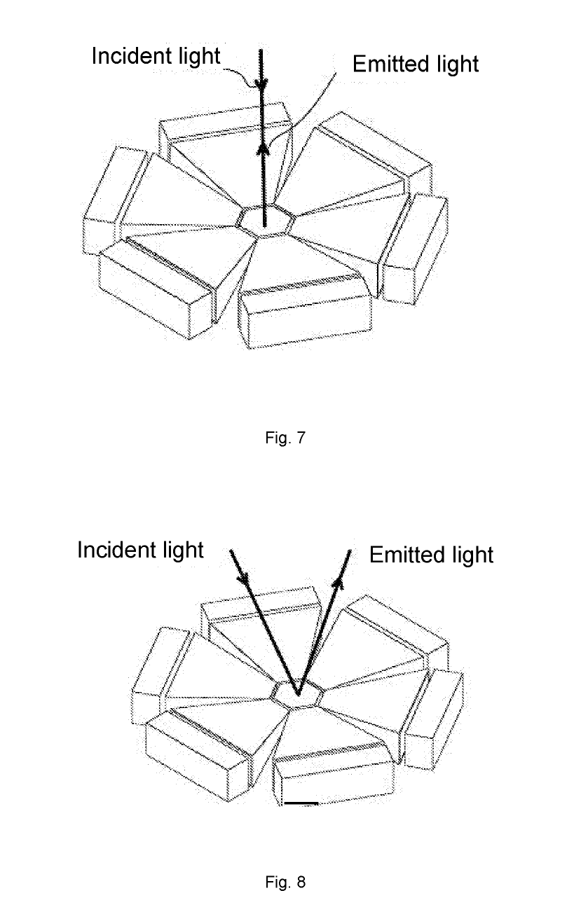

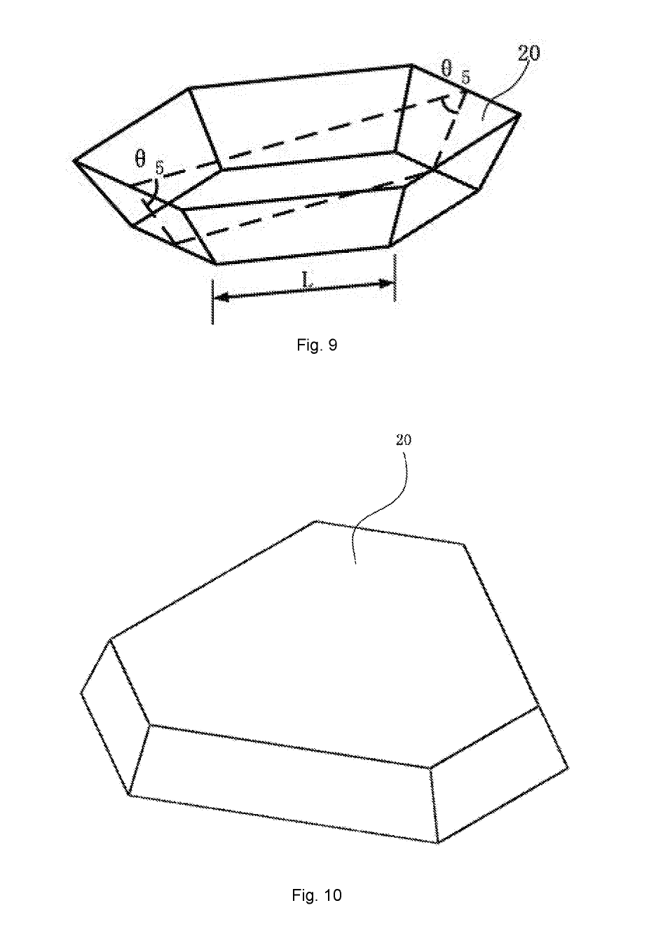

As shown in FIG. 7 and FIG. 8, after the laser needing energy amplification enters from the upside surface of the regular prismoid of the laser medium 20 and extracts energy, the laser is reflected by the reflection film plated on the underside surface of the regular prismoid of the laser medium 20, extracts energy and then is emitted from the upside surface of the regular prismoid of the laser medium 20; specifically, the incident laser enters from the upside surface of the regular prismoid of the laser medium 20 perpendicularly, the incident laser is overlapped with the emitted laser path and is coaxially amplified (shown in FIG. 7); or, the incident laser enters from the upside surface of the regular prismoid of the laser medium 20 at an angle, then the laser is emitted out at a certain angle relative to the incident laser, the incident laser is not overlapped with the emitted laser path and is off-axially amplified (shown in FIG. 8). The axis refers to an optical axis. While off-axial amplification, a reflector group is provided at the laser exit and through the reflector group an off-axial multi-pass amplification is conducted.

The laser amplifier provided by the embodiment can be horizontally or vertically placed and used; when the laser amplifier is horizontally placed and used, the upside surface and the underside surface of the regular prismoid of the laser medium 20 are placed along the horizontal direction; when the laser amplifier is vertically placed and used, the upside surface and the underside surface of the regular prismoid of the laser medium 20 are placed along the vertical direction. What shown in the accompanying drawing is the condition of horizontal placement and use mentioned in the embodiment.

### Embodiment 2

As shown in FIG. 9, the difference between the Embodiment 2 and the Embodiment 1 lies in: in the Embodiment 2, the underside surface of the regular prismoid of the laser medium 20 is at the upper end and the upside surface of the regular prismoid is at the lower end, the laser needing energy amplification enters from the underside surface of the regular prismoid, this is contrary to the setting of the laser medium 20 in Embodiment 1. The aperture of the laser medium 20 is large, the edge length L of the regular polygon of the underside surface of the regular prismoid is greater than or equal to 10 mm. The underside surface of the regular prismoid of the laser medium 20 is plated with a high-transmission film which is consistent with the wavelength of the laser needing energy amplification; the high-transmission film is used to transmit the laser needing energy amplification; the upside surface of the regular prismoid of the laser medium 20 is plated with a reflection film which is consistent with the wavelength of the laser needing energy amplification; and the reflection film is used to reflect the laser needing energy amplification.

In a preferred embodiment, the pumping light is totally reflected in the laser medium 20. After entering into the laser medium 20, the pumping light is totally reflected in the laser medium 20, wherein nearly each reflection is a total reflection; in this way, the pumping light would not be emitted out of the laser medium 20, the laser needing energy amplification can extract the pumping light to the greatest extent, the pumping light has a high energy utilization efficiency and can obtain a higher energy gain. If to enable the pumping light to be totally reflected in the laser medium 20, in a preferred embodiment, in order to enable a greatest number of light rays to be totally reflected and make the range of the incident angle biggest,

$${θ}_{5} = {θ}_{c} = arcsin ( \frac{{n}_{1}}{{n}_{2}} ) .$$

The specific calculation is similar to that in Embodiment 1, and no further description is needed here.

Except above, other structures and working process of this embodiment is similar to those in Embodiment 1, please refer to the description in the Embodiment 1.

### Embodiment 3

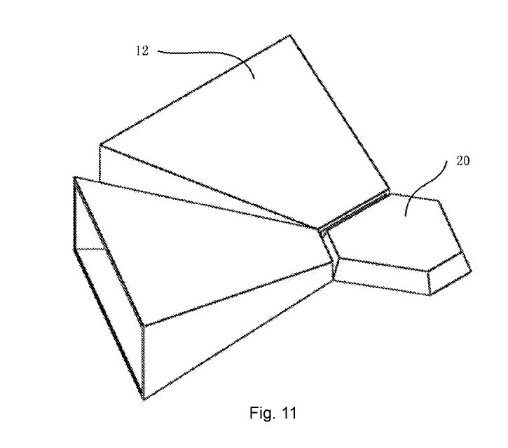

As shown in FIG. 10 and FIG. 11, the difference between the Embodiment 3 and the Embodiment 1 lies in: in the Embodiment 3, the shape of the upside and underside surfaces of the laser medium 20 (that is, a polygonal laser medium) is not a regular polygon, but a common polygon; the shape of the laser medium 20 is a common prismoid, not a regular prismoid; the upside polygon and the downside polygon of the prismoid are similar polygons.

According to the gain uniformity of a gain area, different polygon shapes can be selected to amplify light spots of different requirements; since light spots needing energy amplification might not require a uniform gain (if not requiring uniform gain, the upside and underside surfaces of the laser medium 20 might not be regular polygons), or the light spot needing energy amplification is not circular or square, but elliptic or of other shapes, a common prismoid not a regular prismoid can be selected as the laser medium 20 in this embodiment.

In a preferred scheme of this embodiment, the length of an edge of the polygon of the upside surface of the prismoid of the laser medium 20 is less than the length of a corresponding edge of the polygon of the underside surface, the edge length of the polygon of the upside surface of the prismoid is greater than or equal to 10 mm.

The above embodiments of the disclosure have advantages as follows:

1. In the pumping large-aperture laser medium, compared with the end-face pumping mode in the existing technology, the semiconductor laser diode stack provided in the disclosure is equivalent to being discomposed into several small areas to be packaged, which reduces the volume of each coupling duct and is convenient to adjust; moreover, when the semiconductor laser diode stack has a fault, it is easy to troubleshoot and convenient to maintain and repair.

2. The pumping light is totally reflected in the laser medium; the pumping light has a high energy utilization efficiency and can obtain a higher energy gain.

3. Compared with the existing technology, the technology in the disclosure reduces the height of each coupling duct, improves the coupling efficiency of the pumping light at the exit of coupling duct and improves the quality of the light beam, and thus increases the gain factor of the amplified laser and improves the beam quality of the amplified output laser.

The above are the preferred embodiments of the disclosure only and are not intended to limit the disclosure. Any modification, equivalent substitute and improvement made within the spirit and principle of the disclosure shall fall within the scope of protection of the disclosure.

1. A large-aperture laser amplifier side-pumped by a multi-dimensional laser diode stack, comprising:
multiple pumping light source assemblies, wherein each pumping light source assembly (10) comprises a semiconductor laser diode stack, a beam shaping element and a coupling duct; a light exit near the semiconductor laser diode stack is provided with the beam shaping element and the coupling duct in order;
a laser medium, of which a shape is a prismoid, wherein both an upside surface and an underside surface of the prismoid are polygonal, and the number of edges of each polygon is the same as the number of the pumping light source assemblies, the upside polygon and the underside polygon of the prismoid are similar polygons; and
a cooling device, which is used to cool the laser medium, wherein the laser medium is located on the cooling device;
wherein each side of the laser medium is correspondingly provided with one pumping light source assembly, wherein, in each pumping light source assembly, pumping light emitted from the semiconductor laser diode stack is shaped by the beam shaping element, coupled by the coupling duct, and then enters from the side of the laser medium for side pumping, and thereby amplifying a laser beam, which is incident from the upside surface or the underside surface of the prismoid of the laser medium, needing energy amplification.

2. The large-aperture laser amplifier side-pumped by a multi-dimensional laser diode stack as claimed in claim 1, wherein the pumping light is totally reflected in the laser medium.

3. The large-aperture laser amplifier side-pumped by a multi-dimensional laser diode stack as claimed in claim 1, wherein the shape of the laser medium is a regular prismoid, of which both the upside surface and the underside surface are regular polygons.

4. The large-aperture laser amplifier side-pumped by a multi-dimensional laser diode stack as claimed in claim 2, wherein on a section of the laser medium where a light path of the pump light transmission in the laser medium is located on, supposing an included angle between the side edge and the underside edge of the section is θ₅, when the pump light is totally reflected on the underside surface of the prismoid, supposing n₁ represents an air refractive index, n₂ represents a refractive index of the laser medium, then
$${θ}_{5} = arcsin ( \frac{{n}_{1}}{{n}_{2}} ) ;$$
or
on a section of the laser medium where the light path of the pump light transmission in the laser medium is located on, supposing the included angle between the side edge and the underside edge of the section is θ₅, when the pump light is totally reflected on the upside surface of the prismoid, supposing n₁ represents an air refractive index, n₂ represents the refractive index of the laser medium, then
$${θ}_{5} = arcsin ( \frac{{n}_{1}}{{n}_{2}} ) .$$

5. The large-aperture laser amplifier side-pumped by a multi-dimensional laser diode stack as claimed in claim 1, wherein a length of an edge of the polygon of the upside surface of the prismoid of the laser medium is less than a length of a corresponding edge of the polygon of the underside surface, an edge length of the polygon of the upside surface of the prismoid is greater than or equal to 10 mm.

6. The large-aperture laser amplifier side-pumped by a multi-dimensional laser diode stack as claimed in claim 1, wherein the upside surface of the prismoid of the laser medium is plated with a high-transmission film which is consistent with a wavelength of a laser needing energy amplification; the high-transmission film is used to transmit the laser needing energy amplification; the underside surface of the prismoid of the laser medium is plated with a reflection film which is consistent with the wavelength of the laser needing energy amplification; and the reflection film is used to reflect the laser needing energy amplification; or,
the underside surface of the prismoid of the laser medium is plated with a high-transmission film which is consistent with the wavelength of a laser needing energy amplification; the high-transmission film is used to transmit the laser needing energy amplification; the upside surface of the prismoid of the laser medium is plated with a reflection film which is consistent with the wavelength of the laser needing energy amplification; and the reflection film is used to reflect the laser needing energy amplification.

7. The large-aperture laser amplifier side-pumped by a multi-dimensional laser diode stack as claimed in claim 1, wherein after the laser needing energy amplification enters from the upside surface of the prismoid of the laser medium and extracts energy, the laser is reflected by the reflection film plated on the underside surface of the prismoid of the laser medium, extracts energy and then is emitted from the upside surface of the prismoid of the laser medium; wherein, the incident laser enters from the upside surface of the prismoid of the laser medium perpendicularly, the incident laser is overlapped with the emitted laser path and is coaxially amplified; or, the incident laser enters from the upside surface of the prismoid of the laser medium at an angle, then the laser is emitted out at a certain angle relative to the incident laser, the incident laser is not overlapped with the emitted laser path and is off-axially amplified; or,
after the laser needing energy amplification enters from the underside surface of the prismoid of the laser medium and extracts energy, the laser is reflected by the reflection film plated on the upside surface of the prismoid of the laser medium, extracts energy and then is emitted from the underside surface of the prismoid of the laser medium; wherein, the incident laser enters from the underside surface of the prismoid of the laser medium perpendicularly, the incident laser is overlapped with the emitted laser path and is coaxially amplified; or, the incident laser enters from the underside surface of the prismoid of the laser medium at an angle, then the laser is emitted out at a certain angle relative to the incident laser, the incident laser is not overlapped with the emitted laser path and is off-axially amplified.

8. The large-aperture laser amplifier side-pumped by a multi-dimensional laser diode stack as claimed in claim 7, wherein while off-axis amplification, a reflector group is provided at the laser exit and through the reflector group an off-axis multi-pass amplification is conducted.

9. The large-aperture laser amplifier side-pumped by a multi-dimensional laser diode stack as claimed in claim 1, wherein the number of the pumping light source assemblies is at least 3, correspondingly, the number of the edges of the polygon is at least 3.

10. The large-aperture laser amplifier side-pumped by a multi-dimensional laser diode stack as claimed in claim 1, wherein the underside surface of the prismoid of the laser medium is located on the cooling device; the cooling method of the cooling device is air cooling or water cooling; or,
the upside surface of the prismoid of the laser medium is located on the cooling device; the cooling method of the cooling device is air cooling or water cooling.

11. The large-aperture laser amplifier side-pumped by a multi-dimensional laser diode stack as claimed in claim 1, wherein when the laser amplifier is horizontally placed and used, the upside surface and the underside surface of the prismoid of the laser medium are placed along a horizontal direction;
when the laser amplifier is vertically placed and used, the upside surface and the underside surface of the prismoid of the laser medium are placed along a vertical direction.

12. The large-aperture laser amplifier side-pumped by a multi-dimensional laser diode stack as claimed in claim 2, wherein when the laser amplifier is horizontally placed and used, the upside surface and the underside surface of the prismoid of the laser medium are placed along a horizontal direction;
when the laser amplifier is vertically placed and used, the upside surface and the underside surface of the prismoid of the laser medium are placed along a vertical direction.

13. The large-aperture laser amplifier side-pumped by a multi-dimensional laser diode stack as claimed in claim 3, wherein when the laser amplifier is horizontally placed and used, the upside surface and the underside surface of the prismoid of the laser medium are placed along a horizontal direction;
when the laser amplifier is vertically placed and used, the upside surface and the underside surface of the prismoid of the laser medium are placed along a vertical direction.

14. The large-aperture laser amplifier side-pumped by a multi-dimensional laser diode stack as claimed in claim 4, wherein when the laser amplifier is horizontally placed and used, the upside surface and the underside surface of the prismoid of the laser medium are placed along a horizontal direction;
when the laser amplifier is vertically placed and used, the upside surface and the underside surface of the prismoid of the laser medium are placed along a vertical direction.

15. The large-aperture laser amplifier side-pumped by a multi-dimensional laser diode stack as claimed in claim 5, wherein when the laser amplifier is horizontally placed and used, the upside surface and the underside surface of the prismoid of the laser medium are placed along a horizontal direction;
when the laser amplifier is vertically placed and used, the upside surface and the underside surface of the prismoid of the laser medium are placed along a vertical direction.

16. The large-aperture laser amplifier side-pumped by a multi-dimensional laser diode stack as claimed in claim 6, wherein when the laser amplifier is horizontally placed and used, the upside surface and the underside surface of the prismoid of the laser medium are placed along a horizontal direction;
when the laser amplifier is vertically placed and used, the upside surface and the underside surface of the prismoid of the laser medium are placed along a vertical direction.

17. The large-aperture laser amplifier side-pumped by a multi-dimensional laser diode stack as claimed in claim 7, wherein when the laser amplifier is horizontally placed and used, the upside surface and the underside surface of the prismoid of the laser medium are placed along a horizontal direction;
when the laser amplifier is vertically placed and used, the upside surface and the underside surface of the prismoid of the laser medium are placed along a vertical direction.

18. The large-aperture laser amplifier side-pumped by a multi-dimensional laser diode stack as claimed in claim 8, wherein when the laser amplifier is horizontally placed and used, the upside surface and the underside surface of the prismoid of the laser medium are placed along a horizontal direction;
when the laser amplifier is vertically placed and used, the upside surface and the underside surface of the prismoid of the laser medium are placed along a vertical direction.

19. The large-aperture laser amplifier side-pumped by a multi-dimensional laser diode stack as claimed in claim 9, wherein when the laser amplifier is horizontally placed and used, the upside surface and the underside surface of the prismoid of the laser medium are placed along a horizontal direction;
when the laser amplifier is vertically placed and used, the upside surface and the underside surface of the prismoid of the laser medium are placed along a vertical direction.

20. The large-aperture laser amplifier side-pumped by a multi-dimensional laser diode stack as claimed in claim 10, wherein when the laser amplifier is horizontally placed and used, the upside surface and the underside surface of the prismoid of the laser medium are placed along a horizontal direction;
when the laser amplifier is vertically placed and used, the upside surface and the underside surface of the prismoid of the laser medium are placed along a vertical direction.
